(19) United States
(12) Patent Application Publication
(10) Pub. No.: US 2025/0203771 A1
(43) Pub. Date: Jun. 19, 2025

(54) PRINTED CIRCUIT BOARD, METHOD OF MANUFACTURING A PRINTED CIRCUIT BOARD, ELECTRICAL DEVICE AND MECHANISM

(71) Applicant: Robert Bosch GmbH, Stuttgart (DE)

(72) Inventors: Charles-Edouard De Gryse, Stuttgart (DE); Hang Yu, Plochingen (DE); Johannes Peter Dingeldein, Stuttgart (DE); Matthias Oechsle, Ditzingen-Hirschlanden (DE); Mustafa Uslu, Stuttgart (DE); Thomas Dittert, Stuttgart (DE); Koji Hatanaka, Ludwigsburg (DE)

(21) Appl. No.: 18/980,000

(22) Filed: Dec. 13, 2024

(30) Foreign Application Priority Data
Dec. 14, 2023 (DE) 10 2023 212 706.7

(51) Int. Cl. H05K 1/03; H05K 3/32

(52) U.S. Cl. CPC H05K 1/0393; H05K 3/32; H05K 2201/052; H05K 2201/09254; H05K 2201/09745; H05K 2201/09754; H05K 2201/10037; H05K 2201/10818; H05K 2203/033

(57) ABSTRACT

A printed circuit board includes at least one conductor path and a contact area for contacting an electrical component. The contact area includes at least one contact surface and a recess. The contact surface extends into the recess and the contact surface is connected to the conductor path.

### BACKGROUND

The present invention relates to a printed circuit board, a method of manufacturing a printed circuit board, an electrical device, and a mechanism.

US 2019/148857 A1 discloses a flat connection structure for electrical cables.

DE 10 036 900 A1 shows a method for contacting a flexible printed circuit board with a contact partner and an arrangement of a flexible printed circuit board and contact partners.

JPH08293340A discloses an elastomer connector.

JP2017022217A shows a ceramic wiring plate and housing for electronic components.

### SUMMARY

The core of the invention in the printed circuit board, comprising at least one conductor path and a contact area for contacting an electrical component, is that the contact area comprises at least one contact surface and a recess, wherein the contact surface extends into the recess, wherein the contact surface is connected to the conductor path.

An aspect of the invention is that electrical components with any contact geometry can be contacted by means of the printed circuit board. For this purpose, the contact surface can be laid on a surface of a contact of the electrical component and connected to the contact, in particular in a material-locking manner.

Advantageously, the contact surface extends the entire length of the recess and/or partially covers the recess.

According to one advantageous embodiment, the contact surface comprises a coating, in particular wherein the contact surface comprises a coating on two opposite surfaces. This protects the contact surface from oxidation and/or mechanical stress. Advantageously, the connection of the contact surface to a contact of the electrical component is mechanically supported.

It is advantageous if the contact surface is thicker than the conductor path. Thus, the contact surface can be designed in a robust manner.

It is also advantageous if the contact surface is wider than the conductor path. The electrical contact resistance can thus be reduced.

According to a further advantageous configuration, the printed circuit board comprises at least one connecting bar that connects at least one conductor path to an edge area of the printed circuit board in an electrically conductive manner, wherein the connecting bar is spaced at a distance from the contact area. Thus, the printed circuit board can be contacted by means of the connecting bar for coating the contact surfaces. By arranging the connecting bar outside of the contact area, accidental contacting can be avoided.

It is further advantageous if the printed circuit board comprises at least one further connecting bar, which is arranged between two conductor paths and is interrupted by a recess, wherein the connecting bar is spaced at a distance from the contact area. This enables an electrically conductive connection for coating the contact surfaces by means of the connection bars, which is subsequently interrupted by the recesses in order to prevent short circuits between the conductor paths. By arranging the connecting bar outside of the contact area, accidental contacting can be avoided.

Advantageously, the printed circuit board is embodied as a flexible printed circuit board. It is advantageous to have the printed circuit board be deformable so as to allow for a flexible installation position.

The core of the invention in the method of manufacturing a printed circuit board, in particular as described above or related to the printed circuit board, comprising a conductor path, a contact surface and a connecting bar, consists in that the contact surface is electrically contacted and coated by means of the conductor paths and the connecting bar, wherein the connecting bar is subsequently interrupted, in particular by introducing, in particular punching, a recess into the printed circuit board at the position of the connecting bar.

The background of the invention is that an electrically conductive connection for coating the contact surface is enabled by means of the connecting bar, which is subsequently interrupted by the recess in order to prevent short circuits on the printed circuit board.

The core of the invention in the electrical device, in particular an electrical energy store, is that the electrical energy store comprises a printed circuit board as described above or relating to the printed circuit board and an electrical component, wherein the printed circuit board contacts the electrical component.

An aspect of the invention is that the electrical device can be designed to be compact.

According to one advantageous embodiment, a contact surface of the printed circuit board is connected to a contact pin of the electrical component, in particular connected in a material-locking manner, in particular adhesively connected and/or welded and/or soldered. Any contact geometries of the electrical component can thus be easily contacted.

The core of the invention in the device, in particular the vehicle, is that the device comprises an electric device as described hereinabove.

The above embodiments and further developments can be combined with one another in any desired manner insofar as advantageous. Additional possible embodiments, further developments, and implementations of the invention also include inventive feature combinations not described or explicitly specified hereinabove or hereinafter with respect to exemplary embodiments. The skilled person will in particular also add individual aspects as improvements or additions to the respective basic form of the present invention.

### BRIEF DESCRIPTION OF THE DRAWINGS

In the following section, the invention is explained on the basis of exemplary embodiments, which can result in further inventive features, to which the scope of the invention is however not limited. Two exemplary embodiments are shown in the drawings.

Shown are:

FIG. 1 a schematic illustration of a first exemplary embodiment of an electrical circuit board 1 according to the invention connected to an electrical component 2,

FIG. 2 a top view of the electrical circuit board 1 and the electrical component 2,

FIG. 3 a schematic cross-sectional diagram of the electrical circuit board 1,

FIG. 4 a top view of a second exemplary embodiment of an electrical circuit board 11 according to the invention at a first time during production of the electrical circuit board 11,

FIG. 5 a top view of the second exemplary embodiment of the electrical circuit board 11 according to the invention at a second time after completion of the electrical circuit board 11, and

FIG. 6 a method for manufacturing a printed circuit board 11.

### DETAILED DESCRIPTION

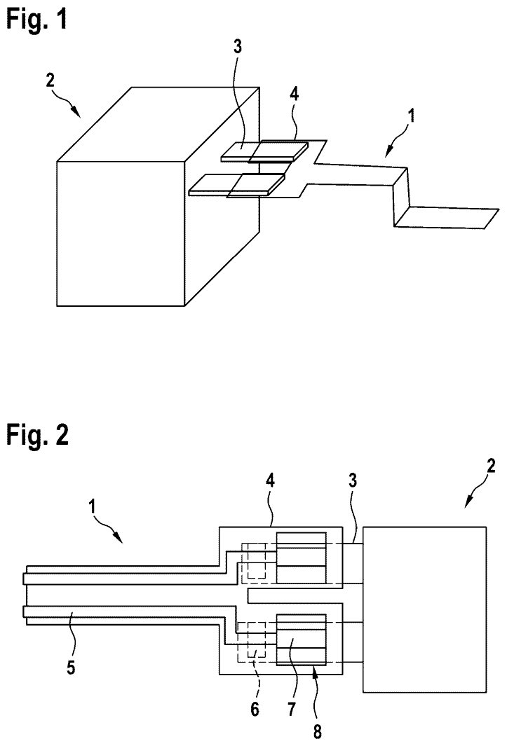

The electrical circuit board 1 shown in FIG. 1 comprises two contact areas 4 for electrically contacting the electrical component 2. The contact areas 4 extend from the printed circuit board 1 to the electrical component 2. The contact areas 4 are spaced apart from one another and extend substantially parallel to one another.

The electrical component 2 comprises two contact pins 3, which stand out from a housing of the electrical component 2. The contact pins 3 are arranged flat.

A respective contact area 4 lies on and is connected to a respective contact pin 3, in particular by a material-locking connection, for example being adhered and/or welded and/or soldered.

Preferably, the printed circuit board 1 is embodied as a flexible printed circuit board.

As shown in FIG. 2, the printed circuit board 1 comprises two conductor paths 5, in particular copper conductor paths, four contact recesses 8 and two contact surfaces 7.

Two contact recesses 8 each extend adjacent a respective contact surface 7 in a direction of extension of the contact surface 7. A contact recess 8 is disposed above the contact surface 7 and the other contact recess 8 is disposed below the contact surface 7.

Each contact area 4 has a contact surface 7 and two contact recesses 8.

Each contact surface 7 is connected to a conductor path 5 within a printed circuit board plane. The conductor paths 5 extend from the contact surfaces 7 and the contact areas 4 into the printed circuit board 1.

A respective contact surface 7 lies on and is connected to a respective contact pin 3, in particular by a material-locking connection, for example adhered and/or welded and/or soldered.

In addition, each contact area 4 is connected to the contact pin 3 by means of an adhesive strip 6 in the region of the conductor path 5. The adhesive strip 6 extends across at least the entire width of the conductor path 5 transversely to the direction of extension of the conductor path 5 and covers it.

The contact surface 7 has a greater width transversely to the direction of extension of the conductor path 5 than the conductor path 5.

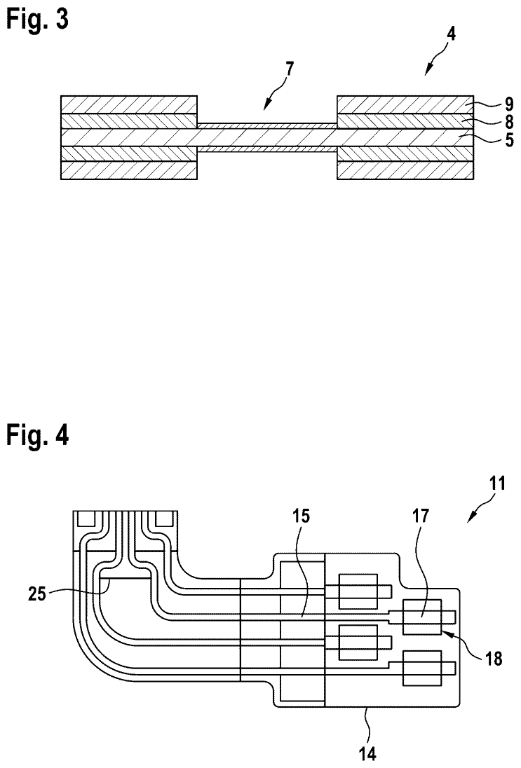

In FIG. 3, the printed circuit board 1 is shown in a cross-sectional view in the area of the contact area 4.

The printed circuit board 1 comprises a conductor path 5 as a conductor plane. The conductor path 5 is arranged between two layers of plastic 9. The conductor path 5 is connected to the respective plastic layer 9 by means of a connecting layer 8. The respective plastic layer 9 is made of polyimide, for example. The respective connecting layer 8 is made of adhesive, for example.

In the area of the contact surface 7, the printed circuit board 1 comprises a metallic coating instead of the plastic layer 9 and the connecting layer 8. For example, the metallic coating is made of tin.

In the area of the contact surface 7, the conductor path 5 is thus reinforced and has a greater thickness than the conductor path 5 between the layers of plastic 9.

FIG. 4 shows a second exemplary embodiment of the electrical printed circuit board 11 during manufacture.

The printed circuit board 11 comprises a contact area 14 in which four contact surfaces 17 are arranged.

The contact surfaces 17 are arranged offset from one another. Each contact surface 17 extends between two contact recesses 18.

Each contact surface 17 is connected to a respective conductor path 15 that extends from the contact area 14 into the printed circuit board 11.

A connecting bar 25 is arranged between two conductor paths 15, respectively. The connecting bars 25 are arranged spaced apart from the contact area 14. At least one connecting bar 25 extends from a conductor path 15 to an edge area of the printed circuit board 11.

The connecting bars 25 serve to electrically contact the conductor paths 15 during the coating of the contact surfaces 17, for example by electroplating. For this purpose, at least one connecting bar 25 is contacted at the edge area of the printed circuit board 11.

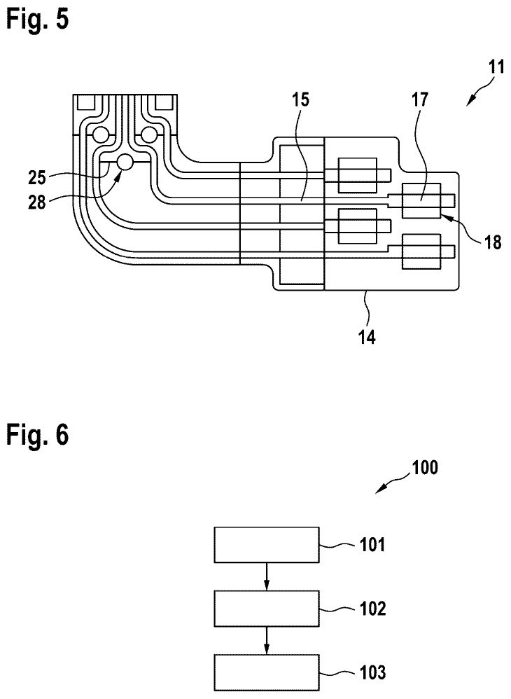

In FIG. 5, the printed circuit board 11 is shown at a second time at which it is completed.

At this time, the printed circuit board 11 differs from the previous description in that the printed circuit board 11 has a recess 28 at the position of each connecting bar 25.

The recesses 28 are introduced into the printed circuit board 11 after the coating of the contact surfaces 17, for example punched, to interrupt the electrically conductive connections between the conductor paths 15. The recesses 28 are arranged spaced apart from the contact area 14.

FIG. 6 shows a method for manufacturing a printed circuit board 11, comprising metallic conductor paths 15, contact surfaces 17 and connecting bars 25, as well as two plastic layers 9.

In a first method step 101, the conductor paths 15, contact surfaces 17 and connecting bars 25 are arranged between and connected to two plastic layers 9. The plastic layers 9 have contact recesses 18 on which the contact surfaces 17 are arranged.

In a second method step 102, the contact surfaces 17 are coated, in particular galvanized. At least one connecting bar 25 is electrically contacted at an edge area of the printed circuit board 11.

In a third method step 103, the connecting bars 25 are interrupted by introducing recesses 28 into the printed circuit board 11. Preferably, the printed circuit board 11 is punched. A respective recess 28 is arranged at the position of each connecting bar 25 so that all connecting bars 25 are electrically insulated.

In this context, an electric energy store is understood to mean a rechargeable energy store, in particular comprising an electrochemical energy store cell and/or an energy store module comprising at least one electrochemical energy store cell and/or an energy store pack comprising at least one energy store module. The energy store cell can be designed as a lithium-based battery cell, in particular a lithium-ion battery cell. Alternatively, the energy store cell is designed as a lithium polymer battery cell or a nickel-metal hydride battery cell or a lead-acid battery cell or a lithium air battery cell or a lithium sulfur battery cell or a sodium-ion battery cell.

A vehicle is understood to mean a land vehicle, e.g., a passenger vehicle or a haul truck, or an aircraft or a marine vehicle, in particular an at least semi-electrically driven vehicle. For example, the vehicle can be a battery-electrically driven vehicle having a purely electric drive, or a hybrid vehicle having an electric drive and an internal combustion engine.

1. A printed circuit board (1, 11) comprising at least one conductor path (5, 15) and a contact area (4, 14) for contacting an electrical component (2),
wherein the contact area (4, 14) comprises at least one contact surface (7, 17) and a recess (8, 18),
wherein the contact surface (7, 17) extends into the recess (8, 18),
wherein the contact surface (7, 17) is connected to the conductor path (5, 15).

2. The printed circuit board (1, 11) according to claim 1, wherein the contact surface (7, 17) comprises a coating.

3. The printed circuit board (1, 11) according to claim 1, wherein the contact surface (7, 17) is wider than the conductor path (5, 15).

4. The printed circuit board (11) according to claim 1, wherein the printed circuit board (11) comprises at least one connecting bar (25) that connects at least one conductor path (15) to an edge area of the printed circuit board (11) in an electrically conductive manner,
wherein the connecting bar (25) is spaced apart from the contact area (14).

5. The printed circuit board (11) according to claim 1, wherein the printed circuit board (11) comprises at least one connecting bar (25) arranged between two conductor paths (15) and interrupted by the recess (28),
wherein the connecting bar (25) is spaced apart from the contact area (14).

6. The printed circuit board (1, 11) according to claim 1, wherein the printed circuit board (1, 11) is a flexible printed circuit board.

7. A method of manufacturing a printed circuit board (1, 11), the printed circuit board comprising a conductor path (5, 15), a contact surface (7, 17) and a connecting bar (25), wherein
the contact surface (7, 17) is electrically contacted and coated by the conductor path (5, 15, and the connecting bar (25),
wherein the connecting bar (25) is subsequently interrupted.

8. An electrical device, comprising a printed circuit board (1, 11) according to claim 1 and an electrical component (2), wherein the printed circuit board (1, 11) contacts the electrical component (2).

9. The electrical device according to claim 8, wherein a contact surface (7, 17) of the printed circuit board (1, 11) is connected to a contact pin (3) of the electrical component (2).

10. A mechanism comprising an electrical device according to claim 8.

11. The printed circuit board (1, 11) according to claim 2, wherein the contact surface (7, 17) comprises a coating on each of two opposed surfaces, and wherein the contact surface (7, 17) is thicker than the conductor path (5, 15).

12. The method according to claim 7, where the connecting bar (25) is interrupted by introducing a recess (28) into the printed circuit board (1, 11) at a position of the connecting bar (25).

13. The method according to claim 12, wherein the recess (28) is introduced by punching.

14. The electrical device according to claim 8, wherein the electrical device is an electrical energy store.

15. The electrical device according to claim 9, wherein the contact surface (7, 17) of the printed circuit board (1, 11) is connected to the contact pin (3) in a material-locking fashion.

16. The electrical device according to claim 15, wherein the contact surface (7, 17) of the printed circuit board (1, 11) is connected to the contact pin (3) adhesively and/or welded, and/or soldered.

17. The mechanism according to claim 10, wherein the mechanism is a vehicle.
